(19) United States
(12) Patent Application Publication
(10) Pub. No.: US 2026/0019745 A1
(43) Pub. Date: Jan. 15, 2026

(54) METHODS AND ELECTRONIC DEVICES

(71) Applicant: Sony Group Corporation, Tokyo (JP)

(72) Inventors: Stefan UHLICH, Stuttgart (DE); Michael ENENKL, Stuttgart (DE); Giorgio FABBRO, Stuttgart (DE); Falk-Martin HOFFMANN, Stuttgart (DE)

(73) Assignee: Sony Group Corporation, Tokyo (JP)

(21) Appl. No.: 18/993,597

(22) PCT Filed: Jul. 17, 2023
(86) PCT No.: PCT/EP2023/069809

§ 371 Date: Jan. 13, 2025

(30) Foreign Application Priority Data
Jul. 21, 2022 (EP) 22186316.0

(51) Int. Cl. H04R 3/00; G06N 3/08; H03F 3/183; H04R 3/02; H04R 29/00

(52) U.S. Cl. CPC H04R 3/007; G06N 3/08; H03F 3/183; H04R 3/02; H04R 29/001; H03F 2200/03

(57) ABSTRACT

A method comprising modifying an input audio signal (u_{playback}(t), s_{playback}(n)) to obtain a modified audio signal (u_{DNN}(t), s_{DNN}(n)) to compensate for nonlinear and/or time-varying distortions effected by a loudspeaker.

### TECHNICAL FIELD

The present disclosure generally pertains to the field of audio reproduction by means of a loudspeaker system.

### TECHNICAL BACKGROUND

Power amplifiers and loudspeakers are the final stages in an audio playback chain. An audio power amplifier amplifies low-power electronic audio signals, such as the signal from a music player to a power level that is high enough for driving the loudspeakers. The loudspeakers convert the electric energy generated by the amplifier into acoustic energy.

Typically, loudspeakers suffer from various e.g. nonlinear effects that cause a poor conversion of the playback signal to the audio waveform. Loudspeakers having fixed, i.e., time-invariant, linear digital filters, e.g., Finite Impulse Response (FIR), infinite Impulse Response (IIR), are traditionally used to compensate for the magnitude and phase distortions of the loudspeaker.

Although there exist techniques for improved playback signal conversion in an audio playback chain, it is generally desirable to provide improved ways of playback signal conversion of an audio input signal.

### SUMMARY

According to a first aspect, the disclosure provides a method comprising modifying an input audio signal to obtain a modified audio signal to compensate for nonlinear and/or time-varying distortions effected by a loudspeaker.

According to a second aspect, the disclosure provides a method for training a neural network, the method comprising determining a feature set of a feedback signal and a feature set of an input audio signal based on the input audio signal; and performing a comparison of the feature set of a feedback signal with the feature set of an input audio signal to obtain a comparison result.

According to a third aspect, the disclosure provides an electronic device comprising circuitry configured to modify an input audio signal to obtain a modified audio signal to compensate for nonlinear and/or time-varying distortions effected by a loudspeaker.

According to a fourth aspect, the disclosure provides an electronic device comprising circuitry configured to determine a feature set of a feedback signal and a feature set of an input audio signal based on the input audio signal; and perform a comparison of the feature set of a feedback signal with the feature set of an input audio signal to obtain a comparison result.

Further aspects are set forth in the dependent claims, the following description, and the drawings.

### BRIEF DESCRIPTION OF THE DRAWINGS

Embodiments are explained by way of example with respect to the accompanying drawings, in which:

FIG. 1 schematically shows an embodiment of a process and system of training a neural network for converting an analog input audio signal into a modified audio signal based on the loudspeaker temperature, causing reduced loudspeaker distortion due to loudspeaker temperature;

FIG. 2 schematically shows an embodiment of a feature sets comparison as performed in FIG. 1;

FIG. 3 schematically shows an embodiment of a system for modifying a driving signal of an amplifier performed by a trained neural network, wherein the loudspeaker temperature is fed back to the system;

FIG. 4 schematically shows an embodiment of a process and system of training a neural network for converting an analog input audio signal into a modified audio signal based on the environmental temperature and the loudspeaker temperature;

FIG. 5 schematically shows an embodiment of a system for modifying a driving signal of an amplifier performed by a trained neural network, wherein the loudspeaker temperature and the environmental temperature is fed back to the system;

FIG. 6 schematically shows an embodiment of a process and system of training a neural network for converting an analog input audio signal into a modified audio signal based on a current and the loudspeaker temperature;

FIG. 7 schematically shows an embodiment of a process and system of training a neural network for converting a digital input audio signal into an output audio signal which reduces loudspeaker distortion due to loudspeaker temperature;

FIG. 8 schematically shows an embodiment of a system for modifying a driving signal of an amplifier performed by a trained neural network, wherein the input signal is a digital signal and the loudspeaker temperature is fed back to the system;

FIG. 9 schematically shows an embodiment of a process and system of training a neural network for converting an analog input audio signal into an output audio signal for preventing loudspeaker damage;

FIG. 10 shows a flow diagram visualizing a method for training a neural network; and

FIG. 11 schematically describes an embodiment of an electronic device that can implement the processes for performing audio signal optimization for compensating for nonlinear and/or time-varying distortions effected by a loudspeaker while protecting the loudspeaker from damage.

### DETAILED DESCRIPTION OF EMBODIMENTS

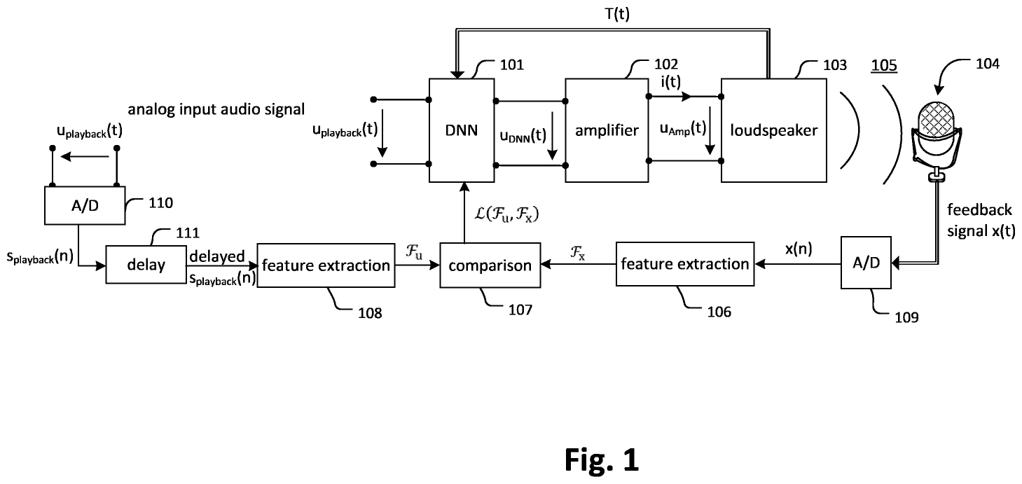

Before a detailed description of the embodiments under reference of FIG. 1 to FIG. 11, general explanations are made.

As indicated in the outset, typically, loudspeakers suffer from various effects, e.g. nonlinear effects, that cause a poor conversion of the playback signal to the audio waveform. Traditionally, time-invariant linear digital filters, e.g., Finite Impulse Response (FIR), infinite Impulse Response (IIR), are used to compensate for the magnitude and phase distortions of the loudspeaker. However, this is only allowing to compensate some static imperfections.

It is known that often a protection circuit is used to protect the coil from overheating where the protection circuit often mainly blocks high DC voltages. These systems usually do not control the loudspeaker in a feedback loop.

It has been recognized that by using a deep neural network (DNN) instead of a digital filter for loudspeaker distortion reduction and a protection circuit for loudspeaker protection, at least one or more of the issues mentioned above, may be addressed.

Consequently, some embodiments pertain to a method comprising modifying an input audio signal to obtain a modified audio signal to compensate for nonlinear and/or time-varying distortions effected by a loudspeaker.

The input audio signal can be an audio signal of any type. It can be in the form of analog signals, digital signals, it can origin from a compact disk, digital video disk, or the like, it can be a data file, such as a wave file, mp3-file or the like, and the present disclosure is not limited to a specific format of the input audio content. An input audio content may for example be a mono audio signal, or a stereo audio signal having a first channel input audio signal and a second channel input audio signal, without that the present disclosure is limited to input audio contents with two audio channels. In other embodiments, the input audio content may include any number of channels, such as a 5.1 audio signal or the like.

Modifying an input audio signal may comprise optimizing an input audio signal to obtain a modified audio signal, such that the output power of the loudspeaker is increased.

The nonlinear and/or time-varying distortions effected by the loudspeaker may be time-variations that might, e.g., occur due to the temperature dependence of the loudspeaker, wherein the temperature may be influenced by the environment temperature as well as the energy of the signal that has already been played back.

The modified audio signal may for example be an audio signal as close as possible to the input audio signal.

In some embodiments, the modified audio signal may be amplified by an amplifier to obtain an amplified signal and the amplified signal is converted into the sound signal by the loudspeaker.

In some embodiments, a parameter obtained at the loudspeaker may be used to obtain the modified audio signal to further compensate for nonlinear and/or time-varying distortions. In other words, the parameter may be used to modify the audio signal to obtain the modified audio signal. The parameter obtained at the loudspeaker may be a temperature of the loudspeaker, for example, a current temperature of the coil of the loudspeaker. The temperature obtained at the loudspeaker may be acquired by a temperature sensor, or the like. This temperature may be influenced by the environment temperature as well as the energy of the signal that has already been played back. Alternatively, the parameter applied to the modified audio signal may be a force or a current driving the loudspeaker. Thus, modifying the audio signal to obtain the modified audio signal may comprise using the parameter to obtain the modified audio signal.

In some embodiments, an external parameter may be used to obtain the modified audio signal to further compensate for nonlinear and/or time-varying distortions. In other words, the external parameter may be used to modify the audio signal to obtain the modified audio signal. For example, in some embodiments, the external parameter may be an environmental temperature acquired by a temperature sensor, or the like. Thus, modifying the audio signal to obtain the modified audio signal may comprise using the external parameter to obtain the modified audio signal.

In some embodiments, using the parameter to obtain the modified audio signal may comprise feeding the parameter, e.g. the temperature to an input layer of a neural network. For example, during the inference phase, by feeding back the parameter obtained at the loudspeaker, e.g. the temperature of the loudspeaker, to the system, the parameter may be input to the input layer of the DNN and may be applied to the modified audio signal to compensate for nonlinear and/or time-varying distortions effected by a loudspeaker. In this manner, the output acoustic signal may be as close as possible to the analog input audio signal

In some embodiments, the neural network may be a deep neural network, DNN. The DNN may act as a protection that can additionally linearize the loudspeaker transfer function. Using the DNN instead of e.g. a linear digital filter, it may be possible to protect the loudspeaker more efficiently and, additionally compensate for nonlinear as well as non-static loudspeaker distortions. Additionally, such a DNN may compensate loudspeaker imperfections and may protect a loudspeaker from overheating and/or damaging.

In some embodiments, the input audio signal may be an analog input audio signal and the modified audio signal may be a modified analog audio signal.

In some embodiments, the input audio signal may be a digital input audio signal and the modified audio signal may be a modified digital audio signal.

In some embodiments, the modified audio signal may be modified in such a way that loudspeaker damage is prevented.

The embodiments also disclose a method for training a neural network, the method comprising determining a feature set of a feedback signal and a feature set of an input audio signal based on the input audio signal; and performing a comparison of the feature set of the feedback signal with the feature set of an input audio signal to obtain a comparison result.

In some embodiments, the method for training a neural network may further comprise performing feature extraction on the feedback signal to obtain the feature set of the feedback signal.

In some embodiments, the method for training a neural network may further comprise performing feature extraction on the input audio signal to obtain the feature set of the input audio signal.

In some embodiments, the method for training a neural network may further comprise obtaining a parameter at a loudspeaker.

In some embodiments, the parameter obtained at the loudspeaker may be a temperature of the loudspeaker. In this manner, if the DNN additionally senses the temperature then it may better linearize the transfer function as well as protect the loudspeaker from being damaged.

In some embodiments, the method for training a neural network may further comprise feeding the parameter to an input layer of the neural network. During the training phase, by feeding back the parameter obtained at the loudspeaker, e.g. the temperature of the loudspeaker to the system, the parameter may be input to the input layer of the DNN and may be used by the DNN to modify the audio signal to compensate for nonlinear and/or time-varying distortions effected by a loudspeaker.

In this manner, the weights of the DNN are learned such that the feedback signal may be as close as possible to the analog input audio signal

In some embodiments, the method for training a neural network may further comprise optimizing neural network weights based on the comparison result and the temperature of the loudspeaker.

In some embodiments, the method for training a neural network may further comprise obtaining an external parameter.

In some embodiments, the external parameter may be an environmental temperature. The environmental temperature may for example be obtained by a temperature sensor. In this manner, if the DNN additionally senses the environmental temperature then it may better linearize the transfer function as well as protect the loudspeaker from being damaged.

In some embodiments, the method for training a neural network may further comprise optimizing neural network weights based on the comparison result and the environmental temperature.

In some embodiments, the method for training a neural network may further comprise optimizing neural network weights based on a force and/or a current driving the loudspeaker. The force and/or a current may be obtained by e.g. a force/acceleration sensor, or the like. For example, the DNN may use as additional sensor input the current and the force in order to monitor the current loudspeaker behavior such that a better driving signal may be generated. Using these additional sensor inputs may also allow to compensate for aging and temperature effects.

In some embodiments, the method for training a neural network may further comprise optimizing neural network weights so that the neural network is configured to modify an audio signal so that loudspeaker damage is prevented. For example, a loss function may be used so that the neural network learns to penalize the solutions that may damage the loudspeaker. In this manner, the modified audio signal may be an audio signal that does not damage the loudspeaker and thus the loudspeaker is protected.

Alternatively, a protection circuit may be integrated to avoid loudspeaker damage. This protection circuit may, e.g., clip the voltage or power that is fed to the loudspeaker. During training phase, the protection circuit may already be included such that the DNN is aware of it and the DNN may learn to drive the loudspeaker with the protection circuit being present, and thus, loudspeaker damage may be prevented while the model is still learned. During the inference phase, the DNN may take over the role of the protection circuit, namely of protecting the loudspeaker. In addition, a protection circuit that avoids any extreme voltage spikes may also be integrated.

In some embodiments, the method for training a neural network may further comprise capturing a reproduced sound signal emitted from the loudspeaker as the feedback signal. The reproduced sound signal emitted from the loudspeaker may be a modified audio signal.

In some embodiments, the method for training a neural network may further comprise modifying the input audio signal based on training parameters to obtain the modified audio signal.

The embodiments also disclose an electronic device comprising circuitry configured to modify an input audio signal to obtain a modified audio signal to compensate for nonlinear and/or time-varying distortions effected by a loudspeaker.

In some embodiments, the circuitry may be configured to use a parameter obtained at the loudspeaker to obtain the modified audio signal to compensate for nonlinear and/or time-varying distortions. In other words, the parameter obtained at the loudspeaker is fed back to the electronic device as a feedback acquired by a sensor. The parameter may be for example a temperature obtained at the inside of the loudspeaker, e.g. the temperature of the coil of the loudspeaker. Alternatively, instead of a parameter obtained at the loudspeaker an external parameter may be fed back to the electronic device as a feedback parameter. The external parameter may be for example the environmental temperature acquired by a temperature sensor.

The embodiments also disclose an electronic device comprising circuitry configured to determine a feature set of a feedback signal and a feature set of an input audio signal based on the input audio signal; and perform a comparison of the feature set of a feedback signal with the feature set of an input audio signal to obtain a comparison result.

### Training Phase

FIG. 1 schematically shows an embodiment of a process and system of training a neural network for converting an analog input audio signal into a modified audio signal based on the loudspeaker temperature, causing reduced loudspeaker distortion due to loudspeaker temperature.

An analog input audio signal u_{playback}(t) is input to a deep neural network 101 (DNN), where t denotes continuous time. The DNN 101 converts the analog signal u_{playback}(t) into a modified audio signal u_{DNN}(t), i.e., it modifies the voltage used to drive an amplifier, such as the amplifier 102. The modified audio signal u_{DNN}(t) is amplified by the amplifier 102 to obtain an amplified audio signal u_{Amp}(t). The amplifier 102 outputs a current i(t) which is used to drive a loudspeaker, such as the loudspeaker 103. The loudspeaker 103 converts the amplified signal u_{Amp}(t) into a sound signal 105. A microphone 104 is configured to capture the reproduced sound signal 105 emitted from loudspeaker 103 as a feedback signal x(t). The feedback signal x(t) is an analog signal and thus here is represented by a double arrow. A parameter obtained at the loudspeaker, here the temperature T(t) of the loudspeaker 103, e.g., the temperature of the coil of the loudspeaker, is acquired by a temperature sensor and fed back to the system. The temperature T(t) is represented by a double arrow since it is an analog signal that is fed back to the system. An analog to digital converter, here A/D 109, transforms the analog feedback signal x(t) to a digital feedback signal x(n). feature extraction 106 is performed on the digital feedback signal x(n) to obtain a feature set [symbol] of the feedback signal. An A/D 110 transforms the analog input audio signal u_{playback}(t) to a digital input audio signal s_{playback}(n). As the audio signal processing needs some time, the feature extraction 108 will receive the feedback signal x(n) with some time lag. That is, there will be an expected latency, for example a time delay Δt, of the feedback signal x(n). In order to compensate this time delay introduced by the audio signal processing (here the processes performed by the DNN 101, the amplifier 102, the loudspeaker 103, the microphone 104, and the A/D 109) the digital audio signal s_{playback}(n) is delayed by a delay 111 to obtain a delayed digital audio signal. This expected time delay is a known, predefined parameter, which may be set in the delay 109 as a predefined parameter. A feature extraction 108 is performed on the delayed digital audio signal s_{playback}(n) to obtain a feature set [symbol] ᵤ of the audio signal. A comparison 107 compares the feature set [symbol] ₓ of the feedback signal x(t) with the feature set [symbol] ᵤ of the analog audio signal u_{playback}(t) to obtain a comparison result [symbol] ( [symbol] ᵤ, [symbol] ₓ) which is fed back to the DNN 101. This comparison result reflects how good the feedback signal x(t) captured by microphone 104 corresponds to the analog audio signal u_{playback}(t) input to DNN 101. The temperature T(t) of the loudspeaker 103 and the result of the comparison of feature set [symbol] ᵤ with feature set [symbol] ₓ are fed back to the DNN 101 for optimizing the weights of the neural network in the training stage.

In the embodiment of FIG. 1, the DNN operates directly on an analog input signal, which may be implemented as proposed by Graf, Hans P., and Lawrence D. Jackel., in the published paper “Analog electronic neural network circuits.” IEEE Circuits and Devices magazine 5.4 (1989): 44-49.

During the training phase, by feeding back the parameter obtained at the loudspeaker, here the temperature T(t) of the loudspeaker 103 to the system, the parameter is input to the input layer of the DNN 101 and is used by the DNN 101 to obtain the modified audio signal u_{DNN}(t) to compensate for nonlinear and/or time-varying distortions effected by a loudspeaker. In this manner, the weights of the DNN are learned such that the feedback signal x(t) is as close as possible to the analog input audio signal u_{playback}(t), i.e., the DNN learns how to drive the loudspeaker with u_{DNN}(t) for a given u_{playback}(t). The DNN 101 is trained to generate an optimized audio signal u_{DNN}(t) which produces a sound signal compensating for nonlinear and/or time-varying distortions effected by a loudspeaker whilst at the same time reproducing the original audio signal u_{playback}(t) as good as possible. In addition, during the training phase the DNN 101 uses the comparison result [symbol] ( [symbol] ᵤ, [symbol] ₓ) to penalize these solutions that may damage the loudspeaker. In this manner, the DNN 101 learns how to modify the input signal accordingly to prevent damaging of the loudspeaker. The training of the DNN 101 may thus be performed in the digital domain where the input of the “trainer” block is the comparison result [symbol] ( [symbol] , [symbol] ₓ) and the output is the changes that need to be applied to every weight, e.g., “slightly increase the weight value”, “keep weight value”, “slightly decrease the weight value”, or the like. A gradient-free method may for example be used to directly update the weights such as disclosed by A. Bhargava et al in “Gradient-Free Neural Network Training via Synaptic-Level Reinforcement Learning”, arXiv:2105.14383.

In the embodiment of FIG. 1, wherein the temperature T(t) of the loudspeaker 103 is fed back into the DNN 101, the current loudspeaker behavior is monitored such that a better driving signal u_{DNN}(t) may be generated. The DNN 101 uses this comparison result together with the sensor input, here temperature T(t) of the loudspeaker 103 for learning how to alter the analog input audio signal u_{playback}(t) such that the temperature of the inside of the loudspeaker is below the predetermined temperature threshold value, while the loudspeaker is not damaged and at the same time its output power is maximized.

It should be noted that using additional sensor inputs may also allow to compensate for aging and temperature effects. These additional sensor inputs may be current i(t), or a force F(t), or a combination of them. The DNN 101 compares a temperature of the coil of the loudspeaker with a predetermined temperature threshold value.

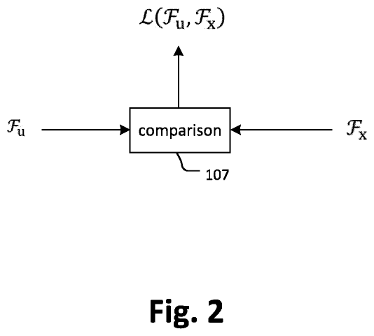

Feature extraction 106 and 108 may for example determine features of the audio signal such as the spectrum of the audio signal. The DNN 101 compares the input audio signal u_{playback}(t) with the feedback signal x(t) and uses this comparison result for learning the weights such that the feedback signal x(t) is as close as possible to the analog input audio signal u_{playback}(t). This comparison is described in more detail in FIG. 2 below.

FIG. 2 schematically shows an embodiment of a feature sets comparison as performed in FIG. 1. As discussed above, the feature sets extracted from the feature extraction 106 and 108 may for example be features of the audio signal such as the spectrum of the input audio signal.

A feature set [symbol] ₓ of the feedback signal x(t) and a feature set [symbol] ᵤ of the analog audio signal u_{playback}(t) are input to the comparison 107 to obtain a comparison result [symbol] ( [symbol] ᵤ, [symbol] ₓ). Comparing the feature sets [symbol] ₓ and [symbol] ᵤ, and optimizing the parameters of a neural network (see DNN 101 in FIG. 1) during the training stage may for example be realized by a loss function [symbol] ( [symbol] ᵤ, [symbol] ₓ) which is designed to generate costs for deviations between [symbol] ₓ and [symbol] ᵤ. [symbol] ( [symbol] , [symbol] ) may for example be designed to penalize if the perceived e.g. spectrum features of the audio content being output from the loudspeaker 103 deviate from the ones of the original signal.

Methods for penalizing are proposed by Vincent E., in published paper Improved perceptual metrics for the evaluation of audio source separation. 10th Int. Conf. on Latent Variable Analysis and Signal Separation (LVA/ICA), March 2012, Tel Aviv, Israel. pp. 430-437. hal-00653196 and by Bitton A., Esling P., Harada T. in published paper Vector-Quantized Timbre Representation, https://arxiv.org/abs/2007.06349.

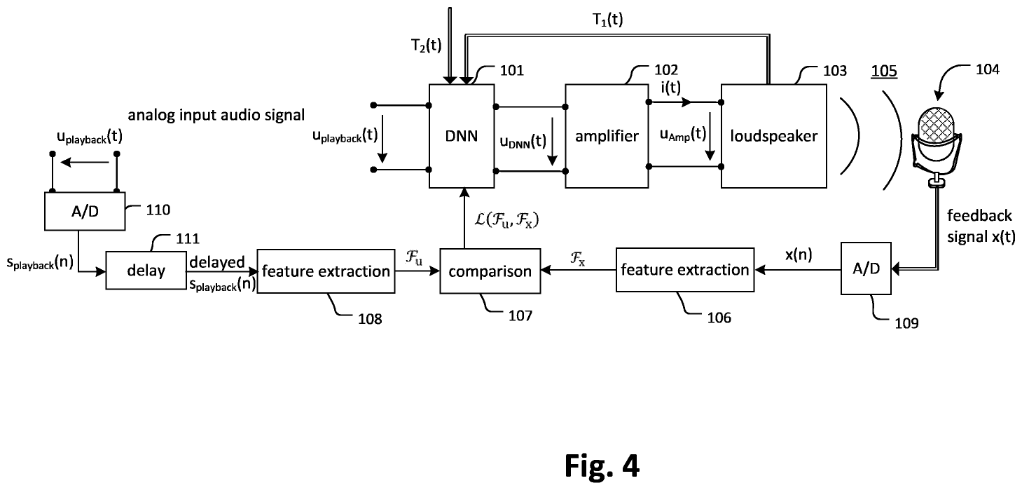

In this way, the DNN 101, using the comparison result [symbol] ( [symbol] , [symbol] ) and the temperature T(t) of the loudspeaker 103 is trained to reduce the distortion on the loudspeaker, by compensating for nonlinear as well as time-varying distortions. Time-variation might, e.g., occur due to the temperature dependence of the loudspeaker, and thus such DNN may better linearize the transfer function as well as protect the loudspeaker from being damaged. Moreover, during the training phase, the DNN 101 may learn to keep the temperature of the loudspeaker within a given temperature range while optimizing for a small distortion/maximum power. In this manner, the protection of the loudspeaker from damage may be learnt. Alternatively, instead of acquiring the current temperature of the coil (inside of the loudspeaker), the temperature from the environment (outside of the loudspeaker) may be acquired. Still alternatively, as described in FIG. 4, such DNN may, additionally to the current temperature of the coil (inside of the loudspeaker), acquire the environmental temperature and thus may further improve linearizing the transfer function as well as protecting the loudspeaker from being damaged.

It should be further noted that the training phase is preferably performed in an anechoic environment or the reflections from the surroundings are masked e.g., by using windowing of the impulse response, in order to capture the direct sound of the loudspeaker 103.

### Inference Phase

After the DNN 101 is trained, no feedback signal x(t) is required to be fed back except from the temperature of the loudspeaker, and the DNN 101 is configured to modify the input audio content for compensating for nonlinear and/or time-varying distortions effected by the loudspeaker while at the same time having a protected loudspeaker, without any supervision.

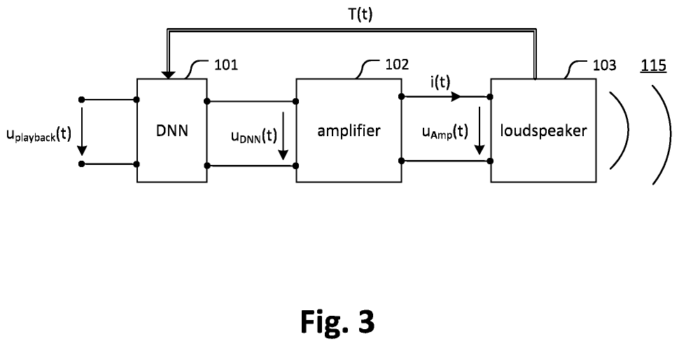

FIG. 3 schematically shows an embodiment of a system for modifying a driving signal of an amplifier performed by a trained neural network, wherein the loudspeaker temperature is fed back to the system. An analog audio signal u_{playback}(t) is input to a deep neural network 101 (DNN), to obtain a modified audio signal u_{DNN}(t), wherein t denotes continuous time. A parameter obtained at the inside of the loudspeaker 103, such as the temperature T(t) of the coil of the loudspeaker 103 is obtained and fed back to the DNN 101. The temperature T(t) is represented by a double arrow since it is an analog signal that is fed back to the system. The temperature T(t) of the loudspeaker 103 may be obtained for example by a temperature sensor. The modified audio signal u_{DNN}(t) is used to drive an amplifier of a loudspeaker 103 and is further modified, if necessary, based on the temperature T(t) of the coil of the loudspeaker 103. The loudspeaker 103 converts the amplified audio signal u_{Amp}(t) into an acoustic signal 115 that compensates for nonlinear and/or time-varying distortions effected by the loudspeaker 103 while at the same time the loudspeaker has an optimized output power and is protected from being damaged due to increased loudspeaker coil temperatures.

During the inference phase, by feeding back the parameter obtained at the loudspeaker, here the temperature T(t) of the loudspeaker 103 to the system, the parameter is input to the input layer of the DNN 101 and is used to obtain the modified audio signal u_{DNN}(t) to compensate for nonlinear and/or time-varying distortions effected by a loudspeaker. In this manner, the output acoustic signal 115 is as close as possible to the analog input audio signal u_{playback}( ).

It should be noted that based on the parameters of the DNN which are learned through the training stage (see FIG. 1), the DNN 101 controls the optimized audio signal 115 that is fed into the amplifier 102 such that the loudspeaker 103 outputs an optimized audio signal 115 compensating for nonlinear and/or time-varying distortions effected by a loudspeaker while at the same time the loudspeaker is protected.

### Environmental Temperature Input

FIG. 4 schematically shows an embodiment of a process and system of training a neural network for converting an analog input audio signal into a modified audio signal based on the environmental temperature and the loudspeaker temperature, with reduced loudspeaker distortion having temperature dependency.

An analog input audio signal u_{playback}(t) is input to a deep neural network 101 (DNN), where t denotes continuous time. The DNN 101 converts the analog signal u_{playback}(t) into a modified audio signal u_{DNN}(t), i.e., it modifies the voltage used to drive an amplifier, such as the amplifier 102. The modified audio signal u_{DNN}(t) is amplified by the amplifier 102 to obtain an amplified audio signal u_{Amp}(t). The amplifier 102 outputs a current i(t) which is used to drive a loudspeaker, such as the loudspeaker 103. The loudspeaker 103 converts the amplified signal u_{Amp}(t) into a sound signal 105. A microphone 104 is configured to capture the reproduced sound signal 105 emitted from loudspeaker 103 as a feedback signal x(t). The feedback signal x(t) is an analog signal and thus here is represented by a double arrow. A parameter obtained at the loudspeaker 103, here a temperature T₁(t) of the loudspeaker 103, e.g., the temperature of the coil of the loudspeaker, is acquired by a temperature sensor and fed back to the system. The temperature T₁(t) is represented by a double arrow since it is an analog signal that is fed back to the system. An analog to digital converter, here A/D 109, transforms the analog feedback signal x(t) to a digital feedback signal x(n). A feature extraction 106 is performed on the feedback signal x(t) to obtain a feature set [symbol] of the feedback signal x(t). An A/D 110 transforms the analog input audio signal u_{playback}(t) to a digital input audio signal s_{playback}(n). As the audio signal processing needs some time, the feature extraction 108 will receive the feedback signal x(n) with some time lag. That is, there will be an expected latency, for example a time delay Δt, of the feedback signal x(n). In order to compensate this time delay introduced by the audio signal processing (here the processes performed by the DNN 101, the amplifier 102, the loudspeaker 103, the microphone 104, and the A/D 109) the digital audio signal s_{playback}(n) is delayed by a delay 111 to obtain a delayed digital audio signal. This expected time delay is a known, predefined parameter, which may be set in the delay 109 as a predefined parameter. Similarly, a feature extraction 108 is performed on the delayed digital audio signal s_{playback}(n) to obtain a feature set [symbol] of the analog audio signal u_{playback}(t) A comparison 107 compares the feature set [symbol] of the feedback signal x(t) with the feature set [symbol] of the analog audio signal u_{playback}(t) to obtain a comparison result L(Fᵤ, [symbol] ) which is fed back to the DNN 101. This comparison result reflects how good the feedback signal x(t) captured by microphone 104 corresponds to the analog audio signal u_{playback}(t) input to DNN 101. An external parameter, here, an environmental temperature T₂(t) is acquired by a temperature sensor and fed back to the system. The temperature T₁(t) of the loudspeaker 103, the environmental temperature T₂(t) and the result of the comparison of feature set [symbol] with feature set [symbol] are fed back to the DNN 101 for optimizing the weights of the neural network in the training stage.

During the training phase, by feeding back to the system the parameter obtained at the loudspeaker, here the temperature T₁(t) of the loudspeaker 103, and the external parameter, here the environmental temperature T₂(t), the parameters are input to the input layer of the DNN 101 and are used to obtain the modified audio signal u_{DNN}(t) to compensate for nonlinear and/or time-varying distortions effected by a loudspeaker. In this manner, the weights of the DNN are learned such that the feedback signal x(t) is as close as possible to the analog input audio signal u_{playback}(t), i.e., the DNN learns how to drive the loudspeaker with u_{DNN}(t) for a given u_{playback}(t). The DNN 101 is trained to generate an optimized audio signal u_{DNN}(n) which produces a sound signal with reduced nonlinear and/or time-varying distortions resulting from a temperature dependency whilst at the same time reproducing the original audio signal u_{playback}(t) as good as possible. During the training phase, the DNN 101 uses the comparison result [symbol] ( [symbol] , [symbol] ) and learns to penalize these solutions that may damage the loudspeaker. In this manner, the DNN 101 is trained to modify the input signal accordingly to prevent damaging of the loudspeaker.

The DNN alters analog audio signal u_{playback}(t) such that the loudspeaker is not damaged but at the same time its output power is maximized while linearizing the transfer function as much as possible, wherein the (non-)linear behavior of the loudspeaker depends on the temperature. Hence, the DNN itself may act as a protection that can additionally linearize the loudspeaker transfer function.

By acquiring the current temperature of the coil of the loudspeaker and the environmental temperature, linearizing the transfer function may further be improved as well as the loudspeaker may further be protected from being damaged.

After the DNN 101 is trained, no feedback signal x(t) and no other input signal are required to be fed back and the DNN 101 is configured to optimize input audio content by having, without any supervision, a reduced loudspeaker distortion and a protected loudspeaker.

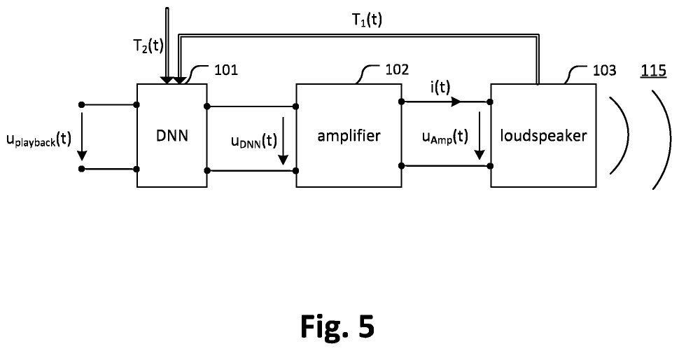

FIG. 5 schematically shows an embodiment of a system for modifying a driving signal of an amplifier performed by a trained neural network, wherein the loudspeaker temperature and the environmental temperature is fed back to the system. An analog audio signal u_{playback}(t) is input to a deep neural network 101 (DNN), to obtain a modified audio signal u_{DNN}(t), wherein t denotes continuous time. A parameter obtained at the inside of the loudspeaker 103, such as the temperature T₁(t) of the coil of the loudspeaker 103 is obtained by a temperature sensor and fed back to the DNN 101. Additionally, an external parameter such as the environmental temperature T₂(t) is obtained by a temperature sensor and fed back to the system. The modified audio signal u_{DNN}(t) is used to drive an amplifier of a loudspeaker 103 and is further modified, if necessary, based on the temperature T₁(t) of the coil of the loudspeaker 103 and the environmental temperature T₂(t). The loudspeaker 103 converts the amplified audio signal u_{Amp}(t) into an acoustic signal having maximized energy while at the same time the loudspeaker, which outputs the acoustic signal 115 compensating for nonlinear and/or time-varying distortions effected by the loudspeaker, is protected from being damaged due to increased coil temperatures.

During the inference phase, by feeding back to the system the parameter obtained at the loudspeaker, here the temperature T₁(t) of the loudspeaker 103, and the external parameter, here the environmental temperature T₂(t), the parameters are input to the input layer of the DNN 101 and are used to obtain the modified audio signal u_{DNN}(t) to compensate for nonlinear and/or time-varying distortions effected by a loudspeaker. In this manner, the output acoustic signal 115 is as close as possible to the analog input audio signal u_{playback}(t).

It should be noted that based on parameters of the DNN which are learned through the training stage (see FIG. 4), the DNN 101 controls the optimized audio signal 115 that is fed into the amplifier 102 such that the loudspeaker 103 outputs an optimized audio signal 115 causing reduced nonlinear and/or time-varying loudspeaker distortions.

### Current Input

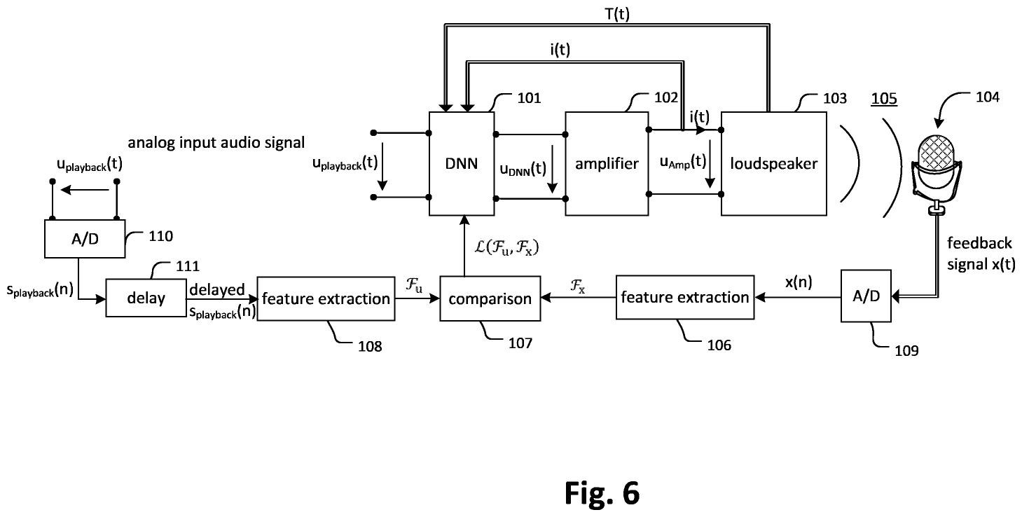

FIG. 6 schematically shows an embodiment of a process and system of training a neural network for converting an analog input audio signal into a modified audio signal based on a current and the loudspeaker temperature.

An analog input audio signal u_{playback}(t) is input to a deep neural network 101 (DNN), where t denotes continuous time. The DNN 101 converts the analog signal u_{playback}(t) into a modified audio signal u_{DNN}(t), i.e., it modifies the voltage used to drive an amplifier, such as the amplifier 102. The modified audio signal u_{DNN}(t) is amplified by the amplifier 102 to obtain an amplified audio signal u_{Amp}(t). The amplifier 102 outputs a current i(t) which is used to drive a loudspeaker, such as the loudspeaker 103. The loudspeaker 103 converts the amplified signal u_{Amp}(t) into a sound signal 105. A microphone 104 is configured to capture the reproduced sound signal 105 emitted from loudspeaker 103 as a feedback signal x(t). The feedback signal x(t) is an analog signal and thus here is represented by a double arrow. A parameter obtained at the loudspeaker, here the temperature T(t) of the loudspeaker 103, e.g., the temperature of the coil of the loudspeaker, is acquired and fed back to the system. The temperature T(t) is represented by a double arrow since it is an analog signal that is fed back to the system. An analog to digital converter, here A/D 109, transforms the analog feedback signal x(t) to a digital feedback signal x(n). The current i(t) associated with driving the loudspeaker 103 is fed back to the system. The current i(t) is an analog signal and thus is shown by a double arrow. A feature extraction 106 is performed on the digital feedback signal x(n) to obtain a feature set. [symbol] of the feedback signal. An A/D 110 transforms the analog input audio signal u_{playback}(t) to a digital input audio signal s_{playback}(n). As the audio signal processing needs some time, the feature extraction 108 will receive the feedback signal x(n) with some time lag. That is, there will be an expected latency, for example a time delay Δt, of the feedback signal x(n). In order to compensate this time delay introduced by the audio signal processing (here the processes performed by the DNN 101, the amplifier 102, the loudspeaker 103, the microphone 104, and the A/D 109) the digital audio signal s_{playback}(n) is delayed by a delay 111 to obtain a delayed digital audio signal. This expected time delay is a known, predefined parameter, which may be set in the delay 109 as a predefined parameter. Similarly, a feature extraction 108 is performed on the delayed digital audio signal s_{playback}(n) to obtain a feature set [symbol] of the analog audio signal u_{playback}(t). A comparison 107 compares the feature set [symbol] of the feedback signal x(t) with the feature set [symbol] of the analog audio signal u_{playback}(t) to obtain a comparison result [symbol] ( [symbol] , [symbol] ) which is fed back to the DNN 101. This comparison result reflects how good the feedback signal x(t) captured by microphone 104 corresponds to the analog audio signal u_{playback}(t) input to DNN 101. The temperature T(t) of the loudspeaker 103, the current i(t) associated with driving the loudspeaker 103 and the result of the comparison of feature set [symbol] with feature set [symbol] are fed back to the DNN 101 for optimizing the weights of the neural network in the training stage. During the training phase, the weights of the DNN are learned such that the feedback signal x(t) is as close as possible to the analog input audio signal u_{playback}(t), i.e., the DNN learns how to drive the louspeaker with u_{DNN}(t) for a given u_{playback}(t). The DNN 101 is trained to generate an optimized audio signal u_{DNN}(n) which produces a sound signal with reduced nonlinear and/or time-varying distortions resulting from e.g. a temperature dependency whilst at the same time reproducing the original audio signal u_{playback}(t) as good as possible.

### Digital DNN

In the embodiments of FIGS. 1 and 4 described above, the DNN 101 operates on the analog audio signal u_{playback}(t).

However, in alternative embodiments, the DNN may operate directly on a digital audio signal s_{playback}(n). When operating on a digital signal, the DNN aims at reducing loudspeaker distortion due to temperature while at the same time protecting the loudspeaker.

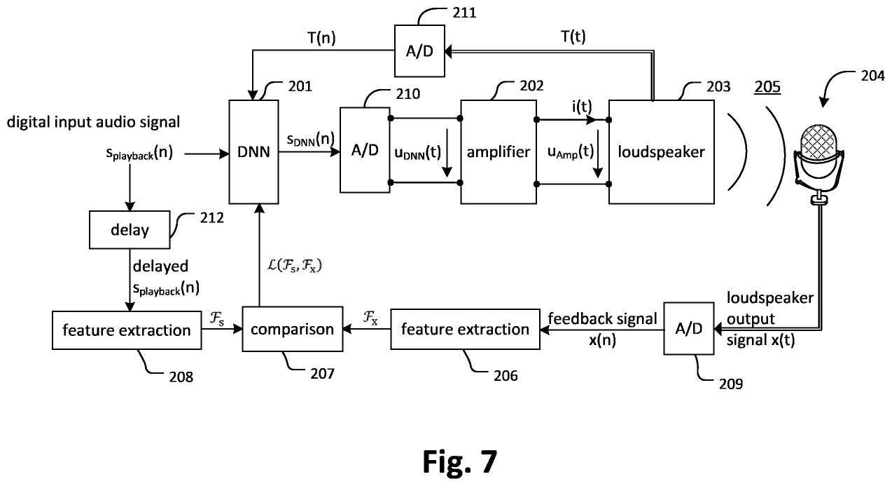

FIG. 7 schematically shows an embodiment of a process and system of training a neural network for converting a digital input audio signal into an output audio signal which reduces loudspeaker distortion due to loudspeaker temperature.

A digital input audio signal s_{playback} (n) is input to a deep neural network 201 (DNN), where n denotes discrete time. The DNN 201 converts the digital signal s_{playback}(n) into a modified audio signal s_{DNN}(n). An A/D conversion 210 transforms the modified digital audio signal s_{DNN}(n) into a modified analog audio signal u_{DNN}(t). The modified analog audio signal u_{DNN}(t) is amplified by the amplifier 202 to obtain an amplified audio signal u_{Amp}(t). A loudspeaker 203 converts the amplified signal u_{Amp}(t) into a sound signal 205. A microphone 204 is configured to capture the reproduced sound signal 205 emitted from loudspeaker 203 as a loudspeaker output signal x(t). A temperature T(t) of the loudspeaker 203, e.g., the temperature of the coil of the loudspeaker, is acquired. An A/D conversion 211 transforms the temperature T(t) into a discrete signal T(n), which is fed back to the system. The temperature T(t) obtained at the loudspeaker 203 is an analog signal and is represented by a double arrow, while the discrete signal T(n) is a digital signal and is represented by a single arrow. An A/D conversion 209 transforms the loudspeaker output signal x(t) captured by a microphone 204 into a digital feedback signal x(n). A feature extraction 206 is per formed on the feedback signal x(t) to obtain a feature set [symbol] of the feedback signal x(n). As the audio signal processing needs some time, the feature extraction 108 will receive the feedback signal x(n) with some time lag. That is, there will be an expected latency, for example a time delay Δt, of the feedback signal x(n). In order to compensate this time delay introduced by the audio signal processing (here the processes performed by the DNN 201, the amplifier 202, the loudspeaker 203, the microphone 204, and the A/D 209) the digital audio signal s_{playback}(n) is delayed by a delay 212 to obtain a delayed digital audio signal. This expected time delay is a known, predefined parameter, which may be set in the delay 212 as a predefined parameter. Similarly, a feature extraction 208 is performed on the digital audio signal s_{playback}(n) to obtain a feature set [symbol] of the digital audio signal s_{playback}(n). A comparison 207 compares the feature set [symbol] of the feedback signal x(n) with the feature set [symbol] of the digital audio signal s_{playback}(n) to obtain a comparison result [symbol] ( [symbol] , [symbol] ) This comparison result reflects how good the feedback signal x(n) captured by microphone 204 corresponds to the digital audio signal s_{playback}(n) input to DNN 201. The temperature T(t) of the loudspeaker 203 and the result of the comparison of feature set [symbol] with feature set [symbol] are fed back to the DNN 201 for optimizing the weights of the neural network in the training stage.

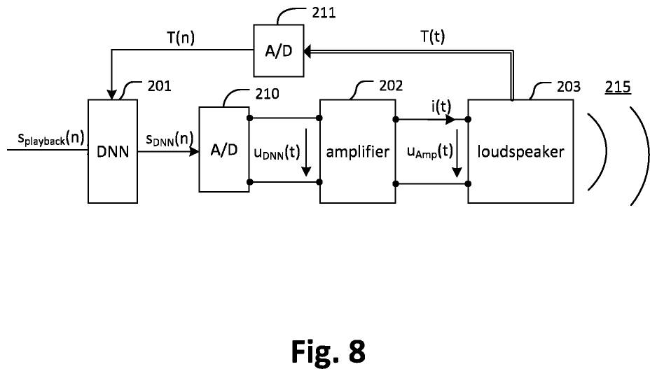

During the training phase, the weights of the DNN are learned such that the feedback signal x(n) is as close as possible to the digital audio signal s_{playback}(n), i.e., the DNN learns how to drive the loudspeaker with s_{DNN}(n) for a given s_{playback}(n). The DNN 201 is trained to generate an optimized audio signal s_{DNN}(n) which produces a sound signal (see 215 in FIG. 8) with reduced nonlinear and/or time-varying distortions resulting from e.g. a temperature dependency whilst reproducing the original audio signal s_{playback}(n) as good as possible.

FIG. 8 schematically shows an embodiment of a system for modifying a driving signal of an amplifier performed by a trained neural network, wherein the input signal is a digital signal, and the loudspeaker temperature is fed back to the system. A digital audio signal s_{playback}(n) is input to a deep neural network 101 (DNN), to obtain a modified audio signal s_{DNN}(n), wherein n denotes discrete time. A parameter obtained at the inside of the loudspeaker 103, such as the temperature T(t) of the coil of the loudspeaker 103 is obtained, converted into a discrete signal T(n) by the A/D 211 and is fed back to the DNN 101. The temperature T(t) of the loudspeaker 103 may be obtained for example by a temperature sensor. The modified audio signal s_{DNN}(n) is converted into a modified analog audio signal u_{DNN}(t), which is used to drive an amplifier of a loudspeaker 103 and is further modified, if necessary, based on the temperature T(t) of the coil of the loudspeaker 103 acquired by a temperature sensor. The loudspeaker 103 converts the amplified audio signal s_{Amp}(n) into an acoustic signal 115 that compensates for nonlinear and/or time-varying distortions effected by the loudspeaker 103 while at the same time the loudspeaker has an optimized output power and is protected from being damaged due to increased loudspeaker coil temperatures.

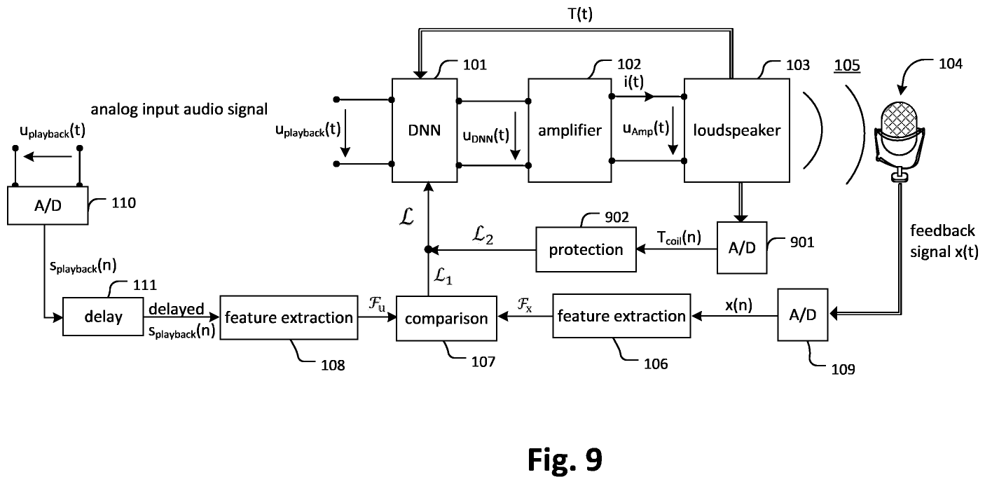

FIG. 9 schematically shows an embodiment of a process and system of training a neural network for converting an analog input audio signal into an output audio signal that prevents loudspeaker damage. As already described in FIG. 1, feature extraction 106 extracts the feature set [symbol] of the feedback signal x(n) and feature extraction 108 extracts the feature set [symbol] of the analog audio signal u_{playback}(t). The feature set [symbol] is compared with the feature set [symbol] to obtain the comparison result [symbol] ( [symbol] , [symbol] ).

Comparing the feature sets [symbol] and [symbol] and optimizing the parameters of neural network 101 during the training stage may for example be realized by a loss function [symbol] which is designed so as to compensate for nonlinear and/or time-varying distortions effected by a loudspeaker while at the same time loudspeaker damage is prevented.

For example, the loss function [symbol] may comprise two components [symbol] ( [symbol] , [symbol] ), and [symbol] (T_{coil}): [symbol] = [symbol] ( [symbol] , [symbol] )+ [symbol] (T_{coil}) Here, the first component [symbol] ( [symbol] , [symbol] ) is designed to reflect how good the feedback signal x(t) captured by microphone 104 corresponds to the analog audio signal u_{playback}(t) input to DNN 101.

The second component [symbol] (T_{coil}) is designed in egg that it penalizes, during training, audio signals that could damage the loudspeaker. For example, [symbol] (T_{coil}) could be configured to not penalize audio signals which result in a coil temperature T_{coil} less than a critical threshold temperate T_{crit} ( [symbol] (T_{coil}))=0 ( [symbol] (T_{coil})=0 for T_{coil}<T_{crit}), but to penalize audio signals which result in a coil temperature T_{coil} equal or over the critical threshold temperate T_{crit}( [symbol] (T_{coil})=C_{penalty} for T_{coil}>=T_{crit}, where C_{penalty} is a predefined constant that defines the penalty attributed to the disfavoured solutions).

In the embodiment of FIG. 9, an A/D 901 transforms the temperature T(t) of the coil of the loudspeaker 103 into a discrete signal T(n), namely T_{coil}(n). A protection 902 is applied to the discrete temperature signal T(n) to obtain the second component [symbol] (T_{coil}) of the loss function [symbol] .

Instead of looking at the coil temperature T_{coil}, in alternative embodiments current and/or voltage might be measured at the loudspeaker, and this measured current and/or voltage might be analysed in order to identify audio signals that might damage the loudspeaker.

### Implementation

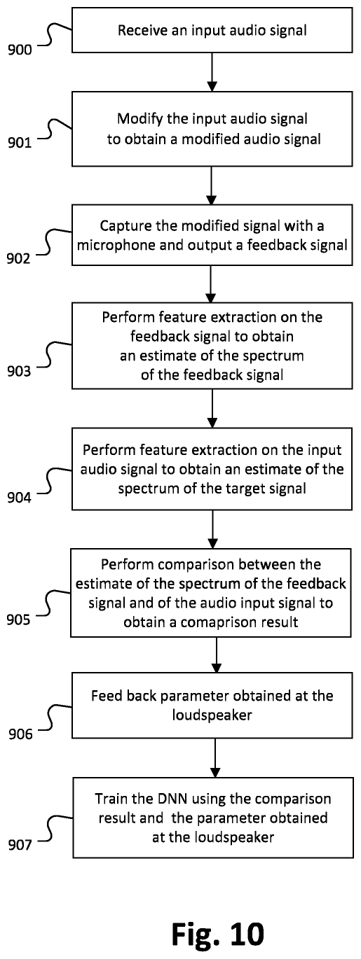

FIG. 10 shows a flow diagram visualizing a method for training a neural network.

At 900, the neural network, such as a deep neural network, DNN, (see 101 in FIGS. 1, 3, 4, 5, 6, 7 and 8) receives an input audio signal. At 901, the DNN modifies the input audio signal to obtain modified audio signal. At 902, a microphone captures the modified audio signal and output a feedback signal (see x(t) in FIGS. 1, 4, 6 and 7). At 903, feature extraction (see 106 in FIGS. 1, 4, 6 and 7) is performed on the feedback signal to obtain an estimate of the spectrum of the feedback signal x(t), e.g., a feature set [symbol] of the feedback signal x(t). At 904, feature extraction (see 108 in FIGS. 1, 4, 6 and 7) is performed on the input audio signal to obtain an estimate of the spectrum of the input audio signal, e.g., a feature set [symbol] , [symbol] of the input audio signal. At 905, comparison is performed be [symbol] tween the estimate [symbol] of the spectrum of the feedback signal x(t) and the estimate [symbol] , [symbol] of the spectrum of the input audio signal to obtain a comparison result (see [symbol] ( [symbol] , Fₓ) in FIGS. 1, 2, 4, 6 and 7). At 906, a parameter obtained at the loudspeaker is fed back to the DNN. At 907, the comparison result, and the parameter obtained at the loudspeaker are transmitted to the DNN and are used to train the DNN. After the DNN 101 is trained, the microphone 104 and the feature extraction 106, 108 are no longer required and the DNN modifies the input audio content such that it outputs a signal to compensate for nonlinear and/or time-varying distortions effected by a loudspeaker, without any supervision, and protecting the loudspeaker from e.g. damaging temperatures.

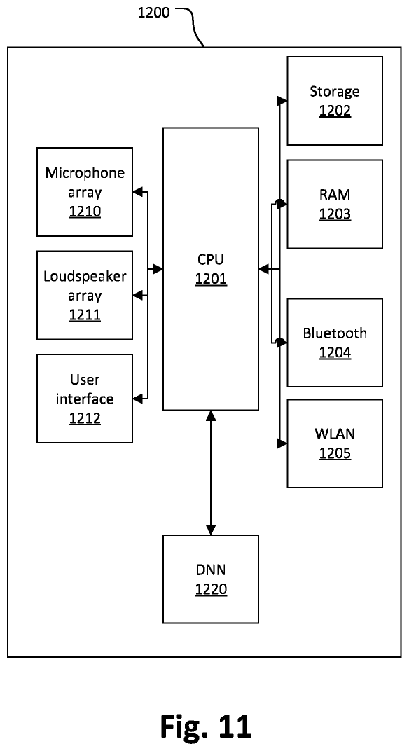

FIG. 11 schematically describes an embodiment of an electronic device that can implement the processes for performing audio signal optimization for compensating for nonlinear and/or time-varying distortions effected by a loudspeaker while protecting the loudspeaker from damage. The electronic device 1200 comprises a CPU 1201 as processor. The electronic device 1200 further comprises a microphone array 1210, a loudspeaker array 1211 and a deep neural network unit 1220 that are connected to the processor 1201. The DNN unit may for example be an artificial neural network in hardware, e.g. a neural network on GPUs or any other hardware specialized for the purpose of implementing an artificial neural network. Loudspeaker array 1211 consists of one or more loudspeakers that are distributed over a predefined space and is configured to render 3D audio. The electronic device 1200 further comprises a user interface 1212 that is connected to the processor 1201. This user interface 1212 acts as a man-machine interface and enables a dialogue between an administrator and the electronic system. For example, an administrator may make configurations to the system using this user interface 1212. The electronic device 1200 further comprises an Ethernet interface 1221, a Bluetooth interface 1204, and a WEAN interface 1205. These units 1204, 1205 act as I/O interfaces for data communication with external devices. For example, additional loudspeakers, microphones, and video cameras with Ethernet, WLAN or Bluetooth connection may be coupled to the processor 1201 via these interfaces 1221, 1204, and 1205.

The electronic system 1200 further comprises a data storage 1202 and a data memory 1203 (here a RAM). The data memory 1203 is arranged to temporarily store or cache data or computer instructions for processing by the processor 1201. The data storage 1202 is arranged as a long-term storage, e.g. for recording sensor data obtained from the microphone array 1210 and provided to or retrieved from the DNN unit 1220. The data storage 1202 may also store audio data that represents audio messages, which the public announcement system may transport to people moving in the predefined space.

It should be noted that the description above is only an example configuration. Alternative configurations may be implemented with additional or other sensors, storage devices, interfaces, or the like. It should be further noted that alternatively the electronic device 1200 may be implemented with a digital signal processor (DSP) or a graphics processing unit (GPU), without limiting the present disclosure in that regard.

It should also be noted that the division of the electronic device of FIG. 11 into units is only made for illustration purposes and that the present disclosure is not limited to any specific division of functions in specific units. For instance, at least parts of the circuitry could be implemented by a respectively programmed processor, field programmable gate array (FPGA), dedicated circuits, and the like.

All units and entities described in this specification and claimed in the appended claims can, if not stated otherwise, be implemented as integrated circuit logic, for example, on a chip, and functionality provided by such units and entities can, if not stated otherwise, be implemented by software.

In so far as the embodiments of the disclosure described above are implemented, at least in part, using software-controlled data processing apparatus, it will be appreciated that a computer program providing such software control and a transmission, storage or other medium by which such a computer program is provided are envisaged as aspects of the present disclosure.

The methods as described herein are also implemented in some embodiments as a computer program causing a computer and/or a processor to perform the method, when being carried out on the computer and/or processor. In some embodiments, also a non-transitory computer-readable recording medium is provided that stores therein a computer program product, which, when executed by a processor, such as the processor described above, causes the methods described herein to be performed.

It should be recognized that the embodiments describe methods with an exemplary ordering of method steps. The specific ordering of method steps is however given for illustrative purposes only and should not be construed as binding. Changes of the ordering of method steps may be apparent to the skilled person.

The method of FIG. 10 can also be implemented as a computer program causing a computer and/or a processor to perform the method, when being carried out on the computer and/or processor. In some embodiments, also a non-transitory computer-readable recording medium is provided that stores therein a computer program product, which, when executed by a processor, such as the processor described above, causes the method described to be performed.

Note that the present technology can also be configured as described below.
(1) A method comprising modifying an input audio signal (u_{playback}(t), s_{playback}(n)) to obtain a modified audio signal (u_{DNN}(t), s_{DNN}(n)) to compensate for nonlinear and/or time-varying distortions effected by a loudspeaker (103).
(2) The method of (1), wherein the modified audio signal (u_{DNN}(t), s_{DNN}(n)) is amplified by an amplifier (102) to obtain an amplified signal and the amplified signal is converted into the sound signal (115) by the loudspeaker (103).
(3) The method of (1) or (2), wherein a parameter obtained at the loudspeaker (103) is used to obtain the modified audio signal (u_{DNN}(t), s_{DNN}(n)) to compensate for nonlinear and/or time-varying distortions.
(4) The method of (3), wherein using the parameter to obtain the modified audio signal (u_{DNN}(t), s_{DNN}(n)) comprises feeding the parameter to an input layer of a neural network.
(5) The method of (4), wherein the neural network is a deep neural network.
(6) The method of (5), wherein the parameter obtained at the loudspeaker (103) is a temperature (T(t); T₁(t)) of the loudspeaker (103).
(7) The method of anyone of (1) to (6), wherein an external parameter is used to obtain the modified audio signal (u_{DNN}(t), s_{DNN}(n)) to compensate for nonlinear and/or time-varying distortions.
(8) The method of (7), wherein the external parameter is an environmental temperature (T₂(t)).
(9) The method of anyone of (1) to (8), wherein the input audio signal (u_{playback}(t), s_{playback}(n)) is an analog input audio signal and the modified audio signal (u_{DNN}(t), s_{DNN}(n)) is a modified analog audio signal (u_{DNN}(t)).
(10) The method of anyone of (1) to (9), wherein the input audio signal (u_{playback}(t), s_{playback}(n)) is a digital input audio signal (s_{playback}(n)) and the modified audio signal (u_{DNN}(t), s_{DNN}(n)) is a modified digital audio signal (s_{DNN} (n))
(11) The method of (1), wherein the modified audio signal (u_{DNN}(t), s_{DNN}(n)) is modified in such a way that loudspeaker damage is prevented.
(12) A method for training a neural network, the method comprising:
   determining a feature set ( [symbol] ) of a feedback signal (x(t)) and a feature set ( [symbol] ) of an input audio signal (u_{playback}(t), s_{playback}(n)) based on the input audio signal (u_{playback}(t, s_{playback}(n)); and
   performing a comparison (107) of the feature set ( [symbol] ) of the feedback signal (x(t)) with the feature set ( [symbol] ) of an input audio signal (u_{playback}(t), s_{playback}(n)) to obtain a comparison result ( [symbol] ( [symbol] , [symbol] )).
(13) The method of (12), wherein the method for training a neural network further comprises performing feature extraction (106) on the feedback signal (x(t)) to obtain the feature set ( [symbol] ) of the feedback signal (x(t)).
(14) The method of (12) or (13), wherein the method for training a neural network further comprises performing feature extraction (108) on the input audio signal (u_{playback}(t), s_{playback}(n)) to obtain the feature set ( [symbol] ) of the input audio signal (u_{playback} (t), s_{playback}(n)).
(15) The method of anyone of (12) to (14), wherein the method for training a neural network further comprises obtaining a parameter at a loudspeaker (103).
(16) The method of (15), wherein the parameter obtained at the loudspeaker (103) is a temperature (T(t); T₁(t)) of the loudspeaker (103).
(17) The method of (16), wherein the method for training a neural network further comprises feeding the parameter to an input layer of the neural network.
(18) The method of (17), wherein the method for training a neural network further comprises optimizing neural network weights based on the comparison result ( [symbol] ( [symbol] , [symbol] )) and the temperature (T(t); T₁(t)) of the loudspeaker (103).
(19) The method of anyone of (12) to (18), wherein the method for training a neural network further comprises obtaining an external parameter.
(20) The method of (19), wherein the external parameter is an environmental temperature (T₂(t)).
(21) The method of (20), wherein the method for training a neural network further comprises optimizing neural network weights based on the comparison result ( [symbol] ( [symbol] , [symbol] )) and the environmental temperature (T₂(t)).
(22) The method of anyone of (12) to (21), wherein the method for training a neural network further comprises optimizing neural network weights based on a force (F(t)) and/or a current (i(t)) driving the loudspeaker (103).
(23) The method of anyone of (12) to (22), wherein the method for training a neural network further comprises capturing a reproduced sound signal (105) emitted from loudspeaker (103) as the feedback signal (x(t)).
(24) The method of (23), wherein the reproduced sound signal (105) emitted from loudspeaker (103) is a modified audio signal (u_{DNN}(t), s_{DNN} (n)).
(25) The method of (24), wherein the method for training a neural network further comprises modifying the input audio signal (u_{playback}(t), s_{playback}(n)) based on training parameters to obtain the modified audio signal (u_{DNN}(t), s_{DNN}(n)).
(26) The method of anyone of (12) to (25), wherein the method for training a neural network further comprises optimizing ( [symbol] ) neural network weights so that the neural network is configured to modify an audio signal (u_{DNN}(t), s_{DNN}(n)) so that loudspeaker damage is prevented.
(27) An electronic device comprising circuitry configured to modify an input audio signal (u_{playback}(t), s_{playback}(n)) to obtain a modified audio signal (u_{DNN}(t), s_{DNN}(n)) to compensate for nonlinear and/or time-varying distortions effected by a loudspeaker (103).
(28) The electronic device of (27), wherein the circuitry is configured to amplify the modified audio signal (u_{DNN}(t), s_{DNN}(n)) to obtain an amplified signal and convert the amplified signal into the sound signal (115).
(29) The electronic of (27) or (28), wherein the circuitry is configured to use a parameter obtained at the loudspeaker (103) to obtain the modified audio signal (u_{DNN}(t), s_{DNN}(n)) to compensate for nonlinear and/or time-varying distortions.
(30) The electronic device of (29), wherein using the parameter to the modified audio signal (u_{DNN}(t), s_{DNN}(n)) comprises feeding the parameter to an input layer of a neural network.
(31) The electronic device of (30), wherein the neural network is a deep neural network.
(32) The electronic device of (31), wherein the parameter obtained at the loudspeaker (103) is a temperature (T(t); T₁(t)) of the loudspeaker (103).
(33) The electronic device of anyone of (27) to (32), wherein the circuitry is configured to use an external parameter to obtain the modified audio signal (u_{DNN}(t), s_{DNN}(n)) to compensate for nonlinear and/or time-varying distortions.
(34) The electronic device of anyone of (33), wherein the external parameter is an environmental temperature (T₂(t)).
(35) The electronic device of anyone of (27) to (34), wherein the input audio signal (u_{playback}(t), s_{playback}(n)) is an analog input audio signal and the modified audio signal (u_{DNN}(t), s_{DNN}(n)) is a modified analog audio signal (u_{DNN}(t)).
(36) The electronic device of anyone of (27) to (34), wherein the input audio signal (u_{playback}(t), s_{playback}(n)) is a digital input audio signal (s_{playback}(n)) and the modified audio signal (u_{DNN}(t), s_{DNN} (n)) is a modified digital audio signal (s_{DNN}(n)).
(37) The electronic device of anyone of (27) to (36), wherein the circuitry is configured to modify the input audio signal (u_{playback}(t), s_{playback}(n)) in such a way that loudspeaker damage is prevented.
(38) An electronic device comprising circuitry configured to:
   determine a feature set ( [symbol] ) of a feedback signal (x(t)) and a feature set ( [symbol] ) of an input audio signal (u_{playback}(t), s_{playback}(n)) based on the input audio signal (u_{playback}(t), s_{playback}(n)); and
   perform a comparison (107) of the feature set ( [symbol] ) of a feedback signal (x(t)) with the feature set ( [symbol] ) of an input audio signal (u_{playback}(t), s_{playback}(n)) to obtain a comparison result ( [symbol] ( [symbol] , [symbol] )).

1. A method comprising modifying an input audio signal to obtain a modified audio signal to compensate for nonlinear and/or time-varying distortions effected by a loudspeaker.

2. The method of claim 1, wherein the modified audio signal is amplified by an amplifier to obtain an amplified signal and the amplified signal is converted into the sound signal the loudspeaker.

3. The method of claim 1, wherein a parameter obtained at the loudspeaker is used to obtain the modified audio signal to compensate for nonlinear and/or time-varying distortions.

4. The method of claim 3, wherein using the parameter to obtain the modified audio signal comprises feeding the parameter to an input layer of a neural network.

5. The method of claim 4, wherein the neural network is a deep neural network.

6. The method of claim 5, wherein the parameter obtained at the loudspeaker is a temperature of the loudspeaker.

7. The method of claim 1, wherein an external parameter is used to obtain the modified audio signal to compensate for nonlinear and/or time-varying distortions.

8. The method of claim 7, wherein the external parameter is an environmental temperature.

9. The method of claim 1, wherein the input audio signal is an analog input audio signal and the modified audio signal is a modified analog audio signal, or wherein the input audio signal is a digital input audio signal and the modified audio signal is a modified digital audio signal.

10. The method of claim 1, wherein the modified audio signal is modified in such a way that loudspeaker damage is prevented.

11. A method for training a neural network, the method comprising:
determining a feature set of a feedback signal and a feature set of an input audio signal based on the input audio signal; and
performing a comparison of the feature set of the feedback signal with the feature set of an input audio signal to obtain a comparison result.

12. The method of claim 11, wherein the method for training a neural network further comprises performing feature extraction on the feedback signal to obtain the feature set of the feedback signal, and/or wherein the method for training a neural network further comprises performing feature extraction on the input audio signal to obtain the feature set of the input audio signal.

13. The method of claim 11, wherein the method for training a neural network further comprises obtaining a parameter at a loudspeaker, wherein the parameter obtained at the loudspeaker is a temperature of the loudspeaker, and wherein the method for training a neural network further comprises feeding the parameter to an input layer of the neural network.

14. The method of claim 13, wherein the method for training a neural network further comprises optimizing neural network weights based on the comparison result and the temperature of the loudspeaker.

15. The method of claim 11 or 14, wherein the method for training a neural network further comprises obtaining an external parameter, and wherein the external parameter is an environmental temperature.

16. The method of claim 15, wherein the method for training a neural network further comprises optimizing neural network weights based on the comparison result and the environmental temperature.

17. The method of claim 11, wherein the method for training a neural network further comprises optimizing neural network weights so that the neural network is configured to modify an audio signal so that loudspeaker damage is prevented.

18. An electronic device comprising circuitry configured to modify an input audio signal to obtain a modified audio signal to compensate for nonlinear and/or time-varying distortions effected by a loudspeaker.

19. The electronic device of claim 18, wherein the circuitry is configured to use a parameter obtained at the loudspeaker to obtain the modified audio signal to compensate for nonlinear and/or time-varying distortions.

20. An electronic device comprising circuitry configured to:
determine a feature set of a feedback signal and a feature set of an input audio signal based on the input audio signal; and
perform a comparison of the feature set of a feedback signal with the feature set of an input audio signal to obtain a comparison result.
